(19) United States
(12) Patent Application Publication
(10) Pub. No.: US 2014/0000680 A1
(43) Pub. Date: Jan. 2, 2014

(54) PHOTOVOLTAIC MODULE WITH INTEGRATED BACK-SHEET AND PROCESS OF MANUFACUTURE

(71) Applicant: E I DU PONT DE NEMOURS AND COMPANY, Wilmington, DE (US)

(72) Inventor: CHEN QIAN ZHAO, NEWARK, DE (US)

(73) Assignee: E I DU PONT DE NEMOURS AND COMPANY, Wilmington, DE (US)

(21) Appl. No.: 13/792,752

(22) Filed: Mar. 11, 2013

Related U.S. Application Data
(60) Provisional application No. 61/664,872, filed on Jun. 27, 2012.

(51) Int. Cl. H01L 31/048

(52) U.S. Cl. CPC H01L 31/0481; H01L 31/0487
USPC 136/251; 438/67

(57) ABSTRACT

A photovoltaic module with a single layer homogeneous integrated back-sheet and a process for forming such a photovoltaic module are provided. The back-sheet comprises 20 to 80 weight percent olefin-based elastomer and 20 to 80 weight percent of inorganic particulates.

### CLAIM OF PRIORITY

This application claims priority from the following U.S. Provisional Application, which is hereby incorporated by reference: Photovoltaic Module Back-Sheet and Process of Manufacture, Application Ser. No. 61/664,872, filed 27 Jun. 2012 (PV0027).

### BACKGROUND OF THE INVENTION

1. Field of the Disclosure

The present invention relates to durable protective sheets for photovoltaic modules, and more particularly to a photovoltaic module with an integrated back-sheet comprising an olefin-based elastomer layer. The invention also relates to a process for manufacturing photovoltaic modules in which a layer of an olefin-based elastomer is adhered directly to the back side of photovoltaic cells of a photovoltaic module.

2. Description of the Related Art

A photovoltaic module (also know as a solar cell module) refers to a photovoltaic device for generating electricity directly from light, particularly, from sunlight. Typically, an array of individual solar cells is electrically interconnected and assembled in a module, and an array of modules is electrically interconnected together in a single installation to provide a desired amount of electricity. If the light absorbing semiconductor material in each cell, and the electrical components used to transfer the electrical energy produced by the cells, can be suitably protected from the environment, photovoltaic modules can last 20, 30, and even 40 or more years without significant degradation in performance.

As shown in FIG. 1, a conventional photovoltaic module 10 is shown in cross section with a light-transmitting substrate 12 or front sheet, an encapsulant layer 14, an active photovoltaic cell layer 16, another encapsulant layer 18 and a protective back-sheet 20. The light-transmitting front sheet substrate, also known as the incident layer, is typically glass or a durable light-transmitting polymer film. The encapsulant layers 14 and 18 adhere the photovoltaic cell layer 16 to the front and back sheets, they seal and protect the photovoltaic cells from moisture and air, and they protect the photovoltaic cells against mechanical impacts such as hail. The encapsulant layers 14 and 18 are typically comprised of a thermoplastic or thermosetting resin such as ethylene-vinyl acetate copolymer (EVA). The photovoltaic cell layer 16 may be any type of solar cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, it helps to dissipate heat generated by the solar cells, and it helps to protect the module wiring and other components against the elements, including heat, water vapor, oxygen and UV radiation. The back-sheet needs to remain intact and adhered to the rest of the module for the service life of the photovoltaic module, which may extend for multiple decades.

Multilayer structures have been employed on the back side of photovoltaic module back-sheets. Highly durable and long lasting fluoropolymer films are used in the structures to resist weathering including degradation by sunlight, provide dielectric strength, and provide good moisture barrier properties all over long periods of time. Polyester films such as polyethylene terephthalate (PET) films are incorporated into the back side structures to provide mechanical strength and electrical insulation. An encapsulant layer, such as a layer of ethylene vinyl acetate (EVA) is used on the back side of the solar cells to seal the cells against air and moisture ingress, to protect the cells against mechanical shocks, and to adhere to the back of the solar cells to the back-sheet. These various layers are adhered to each other by adhesive such as polyurethane or polyolefin adhesives.

There is a need for a photovoltaic module back-sheet that meets all of the requirements of adhesion to the solar cells, sealing of solar cells, moisture and oxygen barrier, electrical insulation, heat dissipation, fire resistance, chemical stability, mechanical strength and protection, and weather resistance over long periods of time, but in a simpler single layer structure. There is a further need for such photovoltaic module back-sheets that is economical to produce and use.

### SUMMARY

A photovoltaic module is provided that comprises a plurality of solar cells having a front light receiving side and an opposite rear side, and a homogeneous single layer integrated back-sheet. The back-sheet has first and second opposite sides wherein the first side is adhered directly to the rear side of the solar cells and the second side forms an exposed surface of the photovoltaic module. The homogeneous single layer integrated back-sheet comprises 20 to 80 weight percent olefin-based elastomer and 20 to 80 weight percent of inorganic particulates, based on the weight of the back-sheet. The olefin-based elastomer is a copolymer comprised of at least 50 weight percent of monomer units selected from ethylene and propylene derived monomer units copolymerized with one or more different C₂₋₂₀ alpha olefin monomer units. The olefin-based elastomer has a melt index of less than 25 g/10 minutes measured according to ASTM D1238. More preferably, the homogeneous single layer integrated back-sheet comprises 30 to 75 weight percent olefin-based elastomer and 25 to 70 weight percent of inorganic particulates, based on the weight of the back-sheet.

In one embodiment, the homogeneous single layer integrated back-sheet comprises at least 10 weight percent of a propylene ethylene elastomer comprised of at least 70 weight percent propylene derived monomer units and at least 10 weight percent of ethylene derived monomer units based on the weight of the propylene ethylene elastomer. In one embodiment, the homogeneous single layer integrated back-sheet comprises and at least 10 weight percent of an ethylene alpha olefin copolymer elastomer comprised of at least 70 weight percent ethylene derived monomer units and at least 1 weight percent of alpha olefin derived monomer units selected from 1-propene, isobutylene, 1-butene, 1-hexane, 4-methyl-1-pentene and 1-octene based on the weight of the ethylene alpha olefin copolymer. In another embodiment, the homogeneous single layer integrated back-sheet comprises at least 10 weight percent of the aforementioned a propylene ethylene elastomer and at least 10 weight percent of aforementioned ethylene alpha olefin copolymer elastomer.

In a preferred embodiment, the inorganic particulates in the homogeneous single layer integrated back-sheet are selected from silica, silicates, calcium carbonate and titanium dioxide particles having an average particle diameter between and including any two of the following diameters: 0.1, 0.2, 15, 45, and 100 microns. In one embodiment, at least 99 percent of the inorganic particulates have an average particle diameter in the range of 0.1 to 45 microns.

The homogeneous single layer integrated back-sheet further comprises 0 to 30 weight percent of one or more of thermoplastic polymer adhesives and tackifiers. In one embodiment, the homogeneous single layer integrated back-sheet comprises 5 to 30 weight percent thermoplastic polymer adhesive that is a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the adhesive copolymer is comprised of at least 50 weight percent ethylene derived units.

The homogeneous single layer integrated back-sheet has a thickness of at least 0.1 mm, and more preferably of from 0.3 to 1.3 mm, and more preferably of 0.35 to 1.0 mm. A metal layer may be on a surface of the back-sheet, as for example in the form of an electric circuit.

A process for forming a the described photovoltaic module is also provided. A polymer melt comprising 20 to 80 weight percent olefin-based elastomer and 20 to 80 weight percent of inorganic particulates, based on the weight of the polymer melt, is provided in which the olefin-based elastomer is a copolymer comprised of at least 50 weight percent of monomer units selected from ethylene and propylene monomer units copolymerized with one or more different C₂₋₂₀ alpha olefin monomer units, and has a melt index of less than 25 g/10 minutes measured according to ASTM D1238. The polymer melt is deposited on a release sheet, passed through a nip and cooled to form a first polymer layer having a thickness of at least 0.1 mm. A first side of the homogeneous single layer integrated back-sheet is pressed directly against the rear side of a plurality of solar cells and heated to adhere the homogeneous single layer integrated back-sheet to the solar cells. An opposite second side of the homogeneous single layer integrated back-sheet forms an exposed exterior surface of the photovoltaic module.

### BRIEF DESCRIPTION OF THE DRAWINGS

The detailed description will refer to the following drawings, wherein like numerals refer to like elements:

FIG. 1 is a cross-sectional view of a conventional photovoltaic module;

FIG. 2 is a schematic view of a process for producing a back-sheet according to one disclosed process;

FIG. 3 is a schematic view of a process for producing a back-sheet according to another disclosed process;

FIG. 4 is a schematic view of a process for producing a back-sheet according to another disclosed process;

FIG. 5 is a cross-sectional view of a photovoltaic module with a disclosed integrated back-sheet.

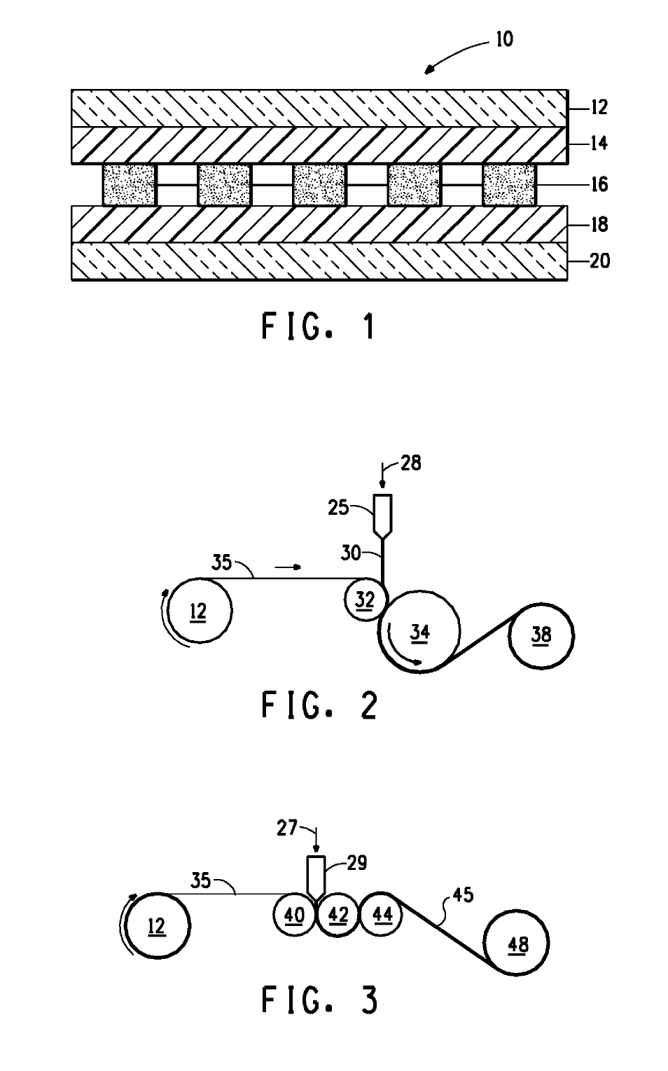

### DETAILED DESCRIPTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

The terms “sheet”, “layer” and “film” are used in their broad sense interchangeably. A “back-sheet” is a sheet, layer or film on the side of a photovoltaic module that faces away from a light source, and is generally opaque. An “integrated back-sheet” is a back-sheet that attaches to the back-side of solar cells and performs functions performed by both encapsulant and back-sheet in a conventional photovoltaic module.

“Encapsulant” means material used to encase the fragile voltage-generating solar cell layer to protect it from environmental or physical damage and hold it in place in a photovoltaic module. Encapsulant layers are conventionally positioned between the solar cell layer and the incident front sheet layer, and between the solar cell layer and the back-sheet backing layer. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to front-sheets, back-sheets, other rigid polymeric sheets and solar cell surfaces, and long term weatherability.

The term “copolymer” is used herein to refer to polymers containing copolymerized units of two different monomers (a dipolymer), or more than two different monomers.

Durable integrated back-sheets for photovoltaic modules are disclosed. Photovoltaic modules incorporating such durable substrates as the module back-sheet are also disclosed. Also disclosed are processes for making such durable back-sheets, and processes for making photovoltaic modules with the durable substrates as the integrated back-sheet. The disclosed durable substrate is a layer of an electrically insulating olefin-based elastomer that is adhered directly to the back side of the solar cells of a photovoltaic module. The olefin-based elastomer layer includes a significant level of inorganic particulate. The olefin-based elastomer layer is a single homogeneous layer with opposite first and second sides where the first side is adhered directly to the back side of the solar cells of the PV module, and the second side is exposed and forms the exterior exposed back surface of a PV module when the integrated back-sheet is used in a PV module.

The disclosed integrated back-sheet comprises a homogeneous electrically insulating polymer layer comprised of an olefin-based elastomer and inorganic particulate material. The olefin-based elastomer layer may optionally include a thermoplastic adhesive or a tackifier. In one aspect, the homogeneous olefin-based elastomer containing layer comprises 20 to 80% by weight of olefin-based elastomer and 20 to 80% by weight of inorganic particulate material, based on the total weight of the olefin-based elastomer containing layer, and more preferably 30 to 75% by weight of olefin-based elastomer and 25 to 70% by weight of inorganic particulate material. The olefin-based elastomer layer may optionally include 5 to 60% by weight of one or more of a thermoplastic polymer adhesive and a tackifier. Most preferably, the homogeneous olefin-based elastomer containing layer is comprised of 40 to 65% by weight of olefin-based elastomer, 35 to 60% by weight of inorganic particulate material, and 0 to 30% by weight of one or more of a thermoplastic polymer adhesive and a tackifier.

As used herein “olefin-based elastomer” means a copolymer comprised of at least 50 wt % of ethylene and/or propylene derived units copolymerized with a different alpha olefin monomer unit selected from C₂₋₂₀ alpha olefins. Preferred olefin-based elastomers are of high molecular weight with a melt index of less than 25 g/10 min, and more preferably less than 15 g/10 min, and even more preferably less than 10 g/10 min based on ASTM D1238. The preferred olefin-based elastomers are polymerized using constrained geometry catalysts such as metallocene catalysts. The preferred olefin-based elastomers provide excellent electrical insulation, good long term chemical stability, as well as high strength, toughness and elasticity. A preferred olefin-based elastomer is comprised of more than 70 wt % propylene derived units copolymerized with comonomer units derived from ethylene or C₄₋₂₀ alpha olefins, for example, ethylene, 1-butene, 1-hexane, 4-methyl-1-pentene and/or 1-octene. A preferred propylene-based elastomer is a semicrystalline copolymer of propylene units copolymerized with ethylene units using constrained geometry catalysts, having a melt index of less than 10 g/10 min (ASTM D1238), that can be obtained from ExxonMobil Chemical of Houston, Tex., under the product names “Vistamaxx™ 6102” and “Vistamaxx™ 6202”. Such propylene-based elastomers are generally described in U.S. Pat. No. 7,863,206. Another preferred olefin-based elastomer is comprised more than 70 wt % ethylene derived units copolymerized with comonomer units derived from C₃₋₂₀ alpha olefins, for example, 1-propene, isobutylene, 1-butene, 1-hexane, 4-methyl-1-pentene and/or 1-octene. A preferred ethylene-based elastomer is a flexible and elastic copolymer comprised of ethylene units copolymerized with alpha olefin units using constrained geometry catalysts, having a melt index of 5 g/10 min (ASTM D1238; 190° C./2.16 Kg), that can be obtained from the Dow Chemical Company of Midland, Mich. under the product name Affinity™ EG8200G. Such ethylene-based elastomers are generally described in U.S. Pat. Nos. 5,272,236 and 5,278,236.

The electrically insulating olefin-based elastomer containing layer further comprises 20% to 80% by weight of inorganic particulates (based on the weight of the layer), and more preferably 25% to 70% by weight of inorganic particulates, and even more preferably 35% to 60% by weight of inorganic particulates. The inorganic particulates may comprise amorphous silica or silicates such as crystallized mineral silicates. Preferred silicates include clay, kaolin, wollastinite, vermiculite, mica and talc (magnesium silicate hydroxide). The inorganic particulate materials may also comprise one or more of calcium carbonate, alumina trihydrate, antimony oxide, magnesium hydroxide, barium sulfate, alumina, titania, titanium dioxide, zinc oxide and boron nitride. Preferred inorganic particulate materials have an average particle diameter less than 100 microns, and preferably less than 45 microns, and more preferably less than 15 microns. If the particle size is too large, defects, voids, pin holes, and surface roughness of the film may be a problem. If the particle size is too small, the particles may be difficult to disperse and the viscosity may be excessively high. Average particle diameters are preferably between and including any two of the following diameters: 0.1, 0.2, 1, 15, 45 and 100 microns. More preferably, the particle diameters of more than 99% of the inorganic particles is between 0.1 and 45 microns, and more preferably between about 0.2 and 15 microns.

The inorganic particulate material adds reinforcement and mechanical strength to the sheet, it reduces sheet shrinkage and curl, and it makes the exposed exterior surface highly weather resistant. Platelet shaped particulates such as mica and talc and/or fibrous particles provide especially good reinforcement. The inorganic particulates also improve heat dissipation from the solar cells to which the integrated back-sheet is attached which reduces the occurrence of hot spots in the solar cells. The presence of the inorganic particulates also improves the fire resistance of the back-sheet. The inorganic particulates also contribute to the electrical insulation properties of the back-sheet. The inorganic particulates may also be selected to increase light refractivity of the back-sheet which serves to increase solar module efficiency and increase the UV resistance of the back-sheet. Inorganic particulate pigments such as titanium dioxide make the sheet whiter, more opaque and more reflective which is often desirable in a photovoltaic module back-sheet. The presence of the inorganic particulates can also serve to reduce the overall cost of the olefin-based elastomer containing back-sheet.

The homogeneous olefin-based elastomer containing back-sheet may optionally further comprise one or more thermoplastic polymer adhesives or tackifiers. The adhesive or tackifier may improve adhesion between the olefin-based elastomer containing substrate and the back of the solar cells when the olefin-based elastomer containing integrated back-sheet is adhered directly to the back of the solar cells.

A preferred thermoplastic adhesive is a polyolefin plastomer such as a non-aromatic ethylene-based copolymer adhesive plastomer of low molecular weight with a melt flow index of greater than 250. Such polyolefin adhesive materials are highly compatible with the olefin-based elastomer, they have low crystallinity, they are non-corrosive, and they provide good adhesion. A preferred polyolefin plastomer is Affinity™ GA 1950 polyolefin plastomer obtained from Dow Chemical Company of Midland, Mich. Other thermoplastic polymer adhesives useful in the disclosed olefin-based elastomer containing back-sheet substrate include ethylene copolymer adhesives such as ethylene acrylic acid copolymers and ethylene acrylate and methacrylate copolymers. Ethylene copolymer adhesives that may be used as the thermoplastic adhesive include copolymers comprised of at least 50 wt % ethylene monomer units, copolymerized in one or more of the following: ethylene-C₁₋₄ alkyl methacrylate copolymers and ethylene-C₁₋₄ alkyl acrylate copolymers; ethylene-methacrylic acid copolymers, ethylene-acrylic acid copolymers, and blends thereof; ethylene-maleic anhydride copolymers; polybasic polymers formed of ethylene monomer units with at least two co-monomers selected from C₁₋₄ alkyl methacrylate, C₁₋₄ alkyl acrylate, ethylene-methacrylic acid, ethylene-acrylic acid and ethylene-maleic anhydride; copolymers formed by ethylene and glycidyl methacrylate with at least one co-monomer selected from C₁₋₄ alkyl methacrylate, C₁₋₄ alkyl acrylate, ethylene-methacrylic acid, ethylene-acrylic acid, and ethylene-maleic anhydride; and blends of two or more of these ethylene copolymers. Another thermoplastic adhesive useful in the olefin-based elastomer containing substrate layer of the disclosed integrated back-sheet is an acrylic hot melt adhesive. Such an acrylic hot melt adhesive may serve as the thermoplastic adhesive on its own or in conjunction with an ethylene copolymer adhesive to improve the adhesion of the olefin-based elastomer layer of the back-sheet to the solar cells. One preferred acrylic hot melt adhesive is Euromelt 707 US synthetic hot melt adhesive from Henkel Corporation of Dusseldorf, Germany. Other thermoplastic adhesives that may be utilized in the olefin-based elastomer substrate layer include polyurethanes, synthetic rubber, and other synthetic polymer adhesives.

Preferred tackifiers useful in the disclosed olefin-based elastomer containing layer of the back-sheet include hydrogenated rosin-based tackifiers, acrylic low molecular weight tackifiers, synthetic rubber tackifiers, hydrogenated polyolefin tackifiers such as polyterpene, and hydrogenated aromatic hydrocarbon tackifiers. Two preferred hydrogenated rosin-based tackifiers include FloraRez 485 glycerol ester hydrogenated rosin tackifier from Florachem Corporation and Stabelite Ester-E hydrogenated rosin-based tackifier from Eastman Chemical.

The homogeneous olefin-based elastomer substrate layer may further comprise additives including, but are not limited to, plasticizers such as polyethylene glycol, processing aides, flow enhancing additives, lubricants, dyes, flame retardants, impact modifiers, nucleating agents to increase crystallinity, antiblocking agents such as silica, thermal stabilizers, hindered amine light stabilizers (HALS), UV absorbers, UV stabilizers, antioxidants, dispersants, surfactants, and primers, and additional reinforcement additives, such as glass fiber and the like.

The olefin-based elastomer, the inorganic particulates, and the optional adhesive or other additives may be compounded and mixed by methods known in the art. This mixture is melted and melt deposited on a release sheet to form the single layer, homogeneous, integrated back-sheet disclosed herein. The release sheet may be a film or layer such as a Mylar® polyester film, wax release paper, or a silicon release sheet.

One process for forming the disclosed integrated back-sheet material is illustrated in FIG. 2. A release sheet 35 is fed from a roll 12 to an extrusion coating station comprising a screw extruder and an extrusion die. An olefin-based elastomer containing melt layer 30 is extruded from an extruder die 25 as a single homogeneous layer.

The olefin-based elastomer containing material 28, which preferably includes olefin-based elastomer compounded with the inorganic particulate material and the optional compatible adhesive and/or other additives, is melted in the extruder and extruded through a slit die to form a melt layer 30 that is extrusion coated onto the surface of the release film 35. The opening of the die is preferably spaced about 10 to 500 mm from the surface of the release film. The die thickness, the melt extrusion rate and the line speed of the release film are adjusted to obtain an olefin-based elastomer containing layer with a thickness of about 0.1 to 1.3 mm, and more preferably with a thickness of about 0.25 to 0.80 mm. The homogeneous polyolefin-based layer is passed on the release film through a nip formed between the rolls 32 and 34. The rolls 32 and 34 are lamination rollers as known in the art, and may have hard or flexible surfaces, and may be heated or cooled depending on the desired processing conditions. The temperature of the rolls 32 and 34 are preferably in the range of 40° to 150° C., and more preferably 50° to 110° C. The roll surfaces may have gloss or matte finishes. The pressure in the nips formed between the rolls 32 and 34 is preferably in the range of about 30 to 100 psi (207 to 690 kPa). The olefin-based elastomer containing layer on the release film is collected on a collection roll 38 after coming off the lamination roller 34.

An alternative process for producing the disclosed integrated back-sheet is schematically illustrated in FIG. 3. The olefin-based elastomer containing material 27, which includes a homogeneous compounded mixture of olefin-based elastomer, inorganic particulate material, and optional compatible adhesive and/or other additives is melted in the extruder 29 and extruded through a slit die directly into a nip formed between the rolls 40 and 42. A release film 35 is also fed into the nip from a roll 12. The single homogeneous layer of olefin-based elastomer containing melt is formed into a sheet layer by the nip between the roll 40 and 42 and by the nip between the roll 42 and the roll 44 to which the olefin-based elastomer containing layer on the release film are transferred. The sheeting rolls 40, 42 and 44 form the olefin-based elastomer containing layer into a uniformly thick layer. The opening of the die is preferably spaced about 10 to 500 mm from the nip between the rolls 40 and 42. The die thickness, the melt extrusion rate, the line speed, and the nip opening are adjusted to obtain an olefin-based elastomer containing layer coating with a thickness of about 0.1 to 1.3 mm, and more preferably with a thickness of about 0.25 to 0.80 mm. The rolls 40, 42 and 44 are quench/nip rolls as known in the art, and may have hard or flexible surfaces, and may be heated or cooled depending on the desired processing conditions. The temperature of the rolls 40, 42 and 44 are preferably in the range of 40° to 150° C., and more preferably 50° to 110° C. The roll surface may have a gloss or matte finish. The nip pressure is preferably in the range of 30 to 90 psi (207 to 621 kPa). The olefin-based elastomer layer 45 on the release sheet is collected on a take-up roll 48. In an alternative embodiment, the olefin-based layer 45 is removed from the release sheet before being collected on a take-up roll.

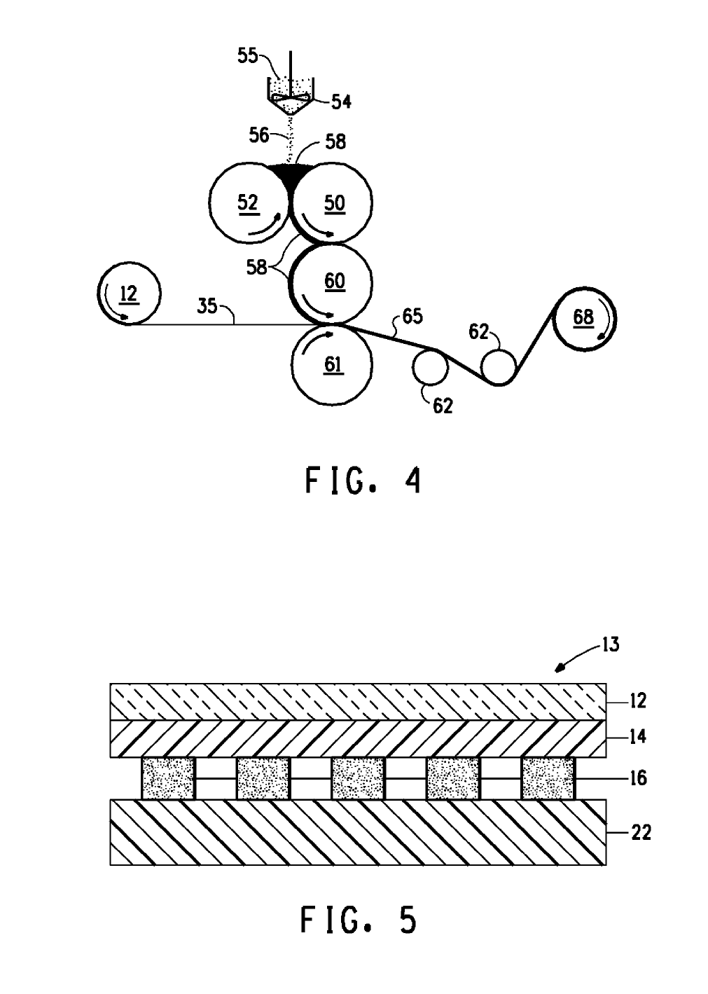

Another alternative process for forming a homogeneous olefin-based elastomer integrated back-sheet is schematically shown in FIG. 4. The olefin-based elastomer, inorganic particulate material, and optional compatible adhesive and/or other additives are mixed in a compounder such a screw compounding machine. The compounded olefin-based elastomer containing mixture is pelletized into pellets 55 and fed into a mixer 54. The pellets are discharged from the mixer 54 as a pellet stream 56 to a melt zone 58 formed between the heated calendar rolls 50 and 52. Preferably the calendar rolls have a chrome plated surface, and are heated to a surface temperature in the range of 40 to 150° C., and more preferably 50 to 110° C. The calendar rolls may have a diameter of form 20 to 60 cm and a length of from 15 cm to 2 m. The calendar rolls 50 and 52 are spaced from each other by about 0.15 to 1.2 mm, and more preferably by about 0.3 to 0.8 mm, depending upon the desired thickness of the olefin-based elastomer layer. A molten film 58 of the melted olefin-based elastomer containing melt is carried on the surface of the heated calendar roll 50 as shown in FIG. 4. The molten film 58 transfers to an adjoining roll 60 located below the calendar roll 50 and that is rotating in the same direction as the calendar roll 50. The roll 60 has a diameter and length similar to the calendar roll 50, but may be larger or smaller. Roll 60 preferably has a chrome plated surface, and is heated to a surface temperature in the range of 20 to 150° C.

A release sheet 35 as described above is fed from a supply roll 12 to a nip formed between the roll 60 and a roll 61. The roll 61 presses the olefin-based elastomer containing material on the surface of the heated calendar roll 60 such that the olefin-based elastomer containing material forms a uniform homogeneous layer on the release sheet 35. The roll 61 has a diameter and length that is similar to the diameter and length of the roll 60, but may be larger or smaller. The roll 61 preferably has a chrome plated surface with a surface speed that is substantially the same as the surface speed of the roll 60. The roll 61 is preferably heated to a surface temperature in the range of 100 to 160° C., and more preferably 110 to 150° C. The olefin-based elastomer containing layer 65 is carried on the release sheet by the transfer rollers 62 to a collection roll 68.

The olefin-based elastomer, inorganic particles, and optional compatible adhesive and/or additives forms a layer that preferably has a thickness in the range of 0.1 to 1.3 mm, and more preferably between 0.25 to 0.80 mm.

One side of the olefin-based elastomer containing layer can be adhered directly to the back side of the solar cell layer and no other encapsulant layer is used on the back side of the solar cell. The olefin-based elastomer containing layer serves the functions of both a back-sheet and an encapsulant layer on the back side of the solar cell. That is, the integrated back-sheet electrically insulates the solar cells, it seals and protects the cells against oxygen, moisture and UV radiation, and it cushions and protects the solar cells against physical impacts such as hail, it dissipates heat, it is fire resistant, and it protects against weather and the elements. A separate conventional encapsulant layer is still used on the front side of the solar cell. FIG. 5 shows a cross-sectional view of an olefin-based elastomer containing sheet 22 as described herein adhered directly to the rear side of the solar cell layer 16. A light transmitting front sheet 12 is adhered to a front encapsulant layer 14 on the front side of the solar cell layer 16. The front sheet 12 is typically a glass or transparent polymer sheet and the encapsulant layer 14 may be a conventional encapsulant such as ethylene vinyl acetate copolymer or ionomer. The olefin-based elastomer containing sheet 22 serves as both the rear encapsulant layer and as the back-sheet of the photovoltaic module 13. The edges of module 13 between the front encapsulant layer 14 and the olefin-based elastomer containing layer 22 can be sealed with a conventional edge seal such as a polybutyl rubber edge seal material.

In another embodiment, the photovoltaic module with an olefin-based elastomer substrate may have one or more metal layers incorporated into the olefin-based elastomer containing layer. The metal layer(s) can be a thin metal foil such as an aluminum, copper or nickel foil, a plated metal layer, a sputtered metal layer or a metal layer deposited by other means such as chemical solution deposition. Preferred metal layers include metal foils, metal oxide layers and sputtered metal layers. Such metal layers provide increased resistance to moisture ingress. Such metal layers can be formed on the surface of the olefin-based elastomer containing layer in the form of circuits that can be electrically connected to the electrical contacts of back-contact solar cells.

The photovoltaic cell layer (also know as the active layer) of the module is made of an ever increasing variety of materials. Within the present invention, a solar cell layer 16 is meant to include any article which can convert light into electrical energy. Typical examples of the various forms of solar cells include, for example, single crystal silicon solar cells, polycrystalline silicon solar cells, microcrystalline silicon solar cells, amorphous silicon based solar cells, copper indium(gallium)diselenide solar cells, cadmium telluride solar cells, compound semiconductor solar cells, dye sensitized solar cells, and the like. The most common types of solar cells include multi-crystalline solar cells, thin film solar cells, compound semiconductor solar cells and amorphous silicon solar cells due to relatively low cost manufacturing ease for large scale solar modules.

The front encapsulant layer 14 of the photovoltaic module is typically comprised of ethylene methacrylic acid and ethylene acrylic acid, ionomers derived therefrom, or combinations thereof. Such encapsulant layers may also be films or sheets comprising poly(vinyl butyral) (PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and poly(ethylene-co-butyl acrylate), ionomers, silicone polymers and epoxy resins. As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn lonomer Resins”, Polyelectrolytes, 1976, C, 177-197. Other suitable ionomers are further described in European patent no. EP1781735. The front encapsulant layer may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like. The front encapsulant layer typically has a thickness greater than or equal to 0.12 mm, and preferably greater than 0.25 mm. A preferred front encapsulant layer has a thickness in the range of 0.5 to 0.8 mm.

The photovoltaic module may further comprise one or more front sheet layers or film layers to serve as the light-transmitting substrate (also know as the incident layer). The light-transmitting layer may be comprised of glass or plastic sheets, such as, polycarbonate, acrylics, polyacrylate, cyclic polyolefins, such as ethylene norbornene polymers, metallocene-catalyzed polystyrene, polyamides, polyesters, fluoropolymers and the like and combinations thereof. Glass most commonly serves as the front sheet incident layer of the photovoltaic module. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass depends on the intended use.

A process of manufacturing the photovoltaic module with a homogeneous olefin-based elastomer containing integrated back-sheet will now be disclosed. The photovoltaic module may be produced through a vacuum lamination process. For example, the photovoltaic module constructs described above may be laid up in a vacuum lamination press and laminated together under vacuum with heat and standard atmospheric or elevated pressure. In an exemplary process, a glass sheet, a front encapsulant layer, a photovoltaic cell layer, and an olefin-based elastomer containing layer are laminated together under heat and pressure and a vacuum to remove air. Preferably, the glass sheet has been washed and dried. In an exemplary procedure, the laminate assembly of the present invention is placed onto a platen of a vacuum laminator that has been heated to about 120° C. The laminator is closed and sealed and a vacuum is drawn in the chamber containing the laminate assembly. After an evacuation period of about 6 minutes, a silicon bladder is lowered over the laminate assembly to apply a positive pressure of about 1 atmosphere over a period of 1 to 2 minutes. The pressure is held for about 14 minutes, after which the pressure is released, the chamber is opened, and the laminate is removed from the chamber.

If desired, the edges of the photovoltaic module may be sealed to reduce moisture and air intrusion by any means known within the art. Such moisture and air intrusion may degrade the efficiency and lifetime of the photovoltaic module. General art edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The described process should not be considered limiting. Essentially, any lamination process known within the art may be used to produce the photovoltaic modules with an integrated back-sheet of an olefin-based elastomer containing layer, as disclosed herein.

While the presently disclosed invention has been illustrated and described with reference to preferred embodiments thereof, it will be appreciated by those skilled in the art that various changes and modifications can be made without departing from the scope of the present invention as defined in the appended claims.

### EXAMPLES

The following Examples are intended to be illustrative of the present invention, and are not intended in any way to limit the scope of the present invention described in the claims.

### Test Methods

### Damp Heat Exposure

The samples are placed into a dark chamber. The samples are mounted at approximately a 45 degree angle to the horizontal. The chamber is then brought to a temperature of 85° C. and relative humidity of 85%. These conditions are maintained for a specified number of hours. Samples are removed and tested after about 1000 hours of exposure. 1000 hours of exposure at 85° C. and 85% relative humidity is the required exposure in many photovoltaic module qualification standards.

### Preparation of Test Mixtures of Olefin-Based Material

The ingredients listed in Table 1 were mixed in a tangential BR Banbury internal mixer made by Farrel Corporation of Ansonia, Conn. The non-polymer additives were charged into the mixing chamber of the Banbury mixer and mixed before the olefin-based copolymer and any thermoplastic polymer adhesive or rosin tackifier ingredients were introduced into the mixing chamber, in what is known as an upside down mixing procedure. The ingredient quantities listed in Table 1 are by weight parts relative to the parts thermoplastic olefin elastomer and other ingredients used in each of the examples.

The speed of the Banbury mixer's rotor was set to 75 rpm and cooling water at tap water temperature was circulated through a cooling jacket around the mixing chamber and through cooling passages in the rotor. The cooling water was circulated to control the heat generated by the mixing. The temperature of the mass being compounded was monitored during mixing. After all of the ingredients were charged into the mixing chamber and the temperature of the mass reached 82° C., a sweep of the mixing chamber was done to make sure that all ingredients were fully mixed into the compounded mass. When the temperature of the compounded mass reached 120° C., it was dumped from the mixing chamber into a metal mold pan.

The compounded mass in the mold pan was then sheeted by feeding the mixture into a 16 inch (40.6 cm) two roll rubber mill. Mixing of the compound was finished on the rubber mill by cross-cutting and cigar rolling the compounded mass. During sheeting, the mass cooled. Sample slabs were prepared by re-sheeting the fully compounded mass on a two roll rubber mill in which the rolls were heated to 80° C. The compound was run between the rolls from five to ten times in order to produce a 20 mil (0.76 mm) thick sheet with smooth surfaces. Six inch by six inch (15.2 cm by 15.2 cm) pre-form squares were die cut from the sheet. A number of the pre-forms were put in a compression mold heated to 100° C., and the mold was put into a mechanical press and subjected to pressure. The mold pressure was initially applied and then quickly released and reapplied two times in what is known as bumping the mold, after which the mold pressure was held for 5 minutes. Cooling water was introduced into the press platens in order to reduce the mold temperature. When the mold cooled to 35° C., the press was opened and the sample substrate slabs were removed.

TABLE 1

| | Sample No. | | | | | |
|---|---|---|---|---|---|---|
| | 1 | 2 | 3 | 4 | 5 | 6 |
| Propylene-based | 45 | 30 | 45 | 45 | 45 | 45 |
| elastomer | | | | | | |
| Ethylene-based | 30 | 30 | 30 | 30 | 30 | 30 |
| elastomer | | | | | | |
| Ethylene alpha olefin | 25 | 10 | 15 | 20 | 15 | 20 |
| copolymer adhesive | | | | | | |
| Ethylene-acrylate | | 30 | | | | |
| copolymer | | | | | | |
| Acrylic hot melt | | | | | 10 | 5 |
| polymer adhesive | | | | | | |
| Tackifier | | | 10 | 5 | | |
| Calcium carbonate | 90 | 90 | 90 | 90 | 90 | 90 |
| particulates | | | | | | |
| Irganox 1010 | 1 | 1 | 1 | 1 | 1 | 1 |
| Tinuvin 1600 | 2.5 | 2.5 | 2.5 | 2.5 | 2.5 | 2.5 |
| Chimassorb 2020 | 1 | 1 | 1 | 1 | 1 | 1 |
| Titanium dioxide | 10 | 10 | 10 | 10 | 10 | 10 |
| Zinc Oxide | 5 | 5 | 5 | 5 | 5 | 5 |
| Stearic Acid | 1.5 | 1.5 | 1.5 | 1.5 | 1.5 | 1.5 |
| Carbowax 3350 | 1.5 | 1.5 | 1.5 | 1.5 | 1.5 | 1.5 |
| Z-6030 Silane | 2 | 2 | 2 | 2 | 2 | 2 |
| Luperox TBEC | 4 | 4 | 4 | 4 | 4 | 4 |
| SR 634 | 4 | 4 | 4 | 4 | 4 | 4 |
| Total Parts | 222.5 | 222.5 | 222.5 | 222.5 | 222.5 | 222.5 |

### Ingredients Glossary

| | |
|---|---|
| Propylene-based elastomer | Vistamaxx ™ 6202 propylene-based elastomer, with a |
| | density of 0.861 g/cm3, melt index of 7.4 g/10 min, and |
| | melt mass-flow rate (MFR)(230° C./2.16 Kg)(by ASTM |
| | D1238). Obtained from ExxonMobil Chemical |
| | Company, Houston, Texas, USA |
| Ethylene-based elastomer | Affinity ™ EG 8200 ethene-1-octene copolymer, with a |
| | density of 0.870 g/cm3, melt index of 5.0 g/10 min, and |
| | melting temperature of 145° F. Obtained from Dow |
| | Chemical Company, Midland, Michigan, USA |
| Ethylene alpha olefin | Affinity 1950 ™ ethene-1-octene copolymer plastomer, |
| copolymer adhesive | with a density of 0.874 g/cm3, and melting temperature |
| | of 158° F. Obtained from Dow Chemical Company, |
| | Midland, Michigan, USA |
| Ethylene-acrylate | Elvaloy ® PTW ethylene-acrylate copolymer |
| copolymer | thermoplastic resin from E.I. DuPont de Nemours and |
| | Company, Wilmington, Delaware, USA |
| Acrylic hot melt polymer | Euromelt 707 US synthetic hot melt polymer adhesive |
| adhesive | from Henkel Corporation of Dusseldorf, Germany |
| Tackifier | FloraRez 485 glycerol ester hydrogenated rosin tackifier |
| | from Florachem Corporation, Jacksonville, Florida, USA |
| Calcium carbonate | Precipitated Calcium Carbonate, with an average |
| particulates | particle size of 0.1 to 1 micron, obtained from Specialty |
| | Minerals, Bethlehem, PA |
| Irganox ® 1010 | [Benzenepropanoic acid, 3,5-bis(1,1-dimethyl)-4- |
| | hydroxy-2,2-bis[3-[3,5-bis(1,1-dimethylethyl)-4- |
| | hydroxyphenyl]-1-oxopropoxy]methyl]-1,3-propanediyl |
| | ester], BASF, Ludwigshafen, Germany |
| Tinuvin 1600 | Triazine derivative, BASF, Ludwigshafen, Germany |
| Chimassorb 2020 | 1,6-Hexanediamine,N,N′-bis(2,2,6,6-tetramethyl-4- |
| | piperidinyl)-polymer with 2,4,6-trichloro-1,3,5-triazine, |
| | reaction products with N-butyl-1-butanamide an N- |
| | butyl-2,2,6,6-tetramethyl-4-piperidinzmine, BASF, |
| | Ludwigshafen, Germany |
| Titanium dioxide | TiPure ® R-960 titanium dioxide from DuPont |
| Zinc Oxide | Zinc oxide, Horsehead Co., Monaca, Pennsylvania, USA |
| Stearic Acid | Stearic acid, PMC Biogenix Inc., Memphis, Tennessee, USA |
| Carbowax 3350 | Carbowax polyethylene glycol 3350 plasticizer from |
| | Dow Chemical Company of Midland, Michigan, USA |
| Z-6030 Silane | Methacryloxypropyl trimethoxysilane, Dow Corning |
| | Inc., Midland, Michigan, USA |
| Luperox TBEC | Carbonoperoxoic acid, OO-(1,1-dimethylethyl) O- |
| | (2-ethylhexyl) ester, Arkema Inc., King of Prussia, |
| | Pennsylvania 19406 |
| SR 634 | Metallic dimethacrylate, Sartomer Company, Inc., |
| | Exton, Pennsylvania, USA |

### Preparation and Testing of Mini Solar Modules

Six inch by six inch (15.2 cm by 15.2 cm) square mini solar modules were prepared from a layered structure of a 5 mm thick low iron glass sheet, followed by an 18 mil (0.46 mm) thick ethylene vinyl acetate encapsulant layer (Photocap® EVA sheet from specialized Technology Resources Inc. of Enfield, Conn.), followed by a mono-crystalline silicon solar cell with a back side contact made of aluminum and iso butyl rubber edge seals, followed the 0.76 mm thick olefin elastomer containing slab of Table 1, followed by a 5 mil thick cell support release sheet made of Teflon® PTFE, followed by a PTFE based heat bumper. The cell had electrical connects to the outside at desired locations.

Each layered structure was placed into a lamination press having a platen heated to about 120-150° C. Each layered structure was allowed to rest on the platen for about 6 minutes to preheat the layered structure under vacuum. The lamination press was activated and the layered structure was pressed together using 1 atmosphere of pressure for 14 minutes to permit the olefin-based elastomer containing layer and front encapsulant to encapsulate silicon solar cell. Each mini solar module was cooled and removed from the press.

The mini modules were tested prior to exposure to damp heat and after 1000 hours of damp heat exposure, as described above. The test was conducted according to Section 10.15 of IEC 61215. Maximum power (Pmax), short circuit current (Isc), open circuit voltage (Voc), series resistance (Rs), and shunt resistance (Rsh) were determined using a Spire SLP 4600 solar simulator. Prior to any testing, the instrument was calibrated using an NREL certified solar module (Kyocera 87 watt module). The thermal coefficient for 5 inch JA Solar cells was used. The following standard conditions for single cell 5 inch modules were used:

Lamp intensity=100 mW/cm²

Fixed starting load voltage=7.2 V

Fixed voltage range=25 V

Fixed current range=6 A

The measured values for each mini module are report in Table 3 below.

TABLE 3

| | Example | | | | | |
|---|---|---|---|---|---|---|
| | 7 | 8 | 9 | 10 | 11 | 12 |
| Slab Sample | 1 | 2 | 3 | 4 | 5 | 6 |
| No. | | | | | | |
| Pₘₐₓ (W) | 2.541 | 2.574 | 2.516 | 2.515 | 2.527 | 2.535 |
| (initial) | | | | | | |
| Pₘₐₓ (W) | 2.555 | 2.575 | 2.550 | 2.535 | 2.528 | 2.537 |
| (1000 hrs DH) | | | | | | |
| Isc (A) (initial) | 5.470 | 5.557 | 5.459 | 5.452 | 5.518 | 5.473 |
| Isc (A) | 5.479 | 5.572 | 5.363 | 5.349 | 5.385 | 5.353 |
| (1000 hrs DH) | | | | | | |
| Voc (V) | 0.622 | 0.622 | 0.619 | 0.620 | 0.618 | 0.619 |
| (initial) | | | | | | |
| Voc (V) | 0.626 | 0.625 | 0.625 | 0.624 | 0.623 | 0.625 |
| (1000 hrs DH) | | | | | | |
| Rs (Ω) (initial) | 0.011 | 0.010 | 0.013 | 0.012 | 0.012 | 0.011 |
| Rs (Ω) | 0.011 | 0.010 | 0.011 | 0.011 | 0.012 | 0.012 |
| (1000 hrs DH) | | | | | | |
| Rsh (Ω) | 60.494 | 39.653 | 64.611 | 51.068 | 57.193 | 60.093 |
| (initial) | | | | | | |
| Rsh (Ω) | 61.033 | 34.512 | 24.285 | 24.113 | 28.792 | 22.565 |
| (1000 hrs DH) | | | | | | |

What is claimed is:

1. A photovoltaic module comprising:
a plurality of solar cells having a front light receiving side and an opposite rear side;
a homogeneous single layer integrated back-sheet having first and second opposite side, said homogeneous single layer integrated back-sheet comprising 20 to 80 weight percent olefin-based elastomer, 20 to 80 weight percent of inorganic particulates, based on the weight of the back-sheet, wherein said olefin-based elastomer is a copolymer comprised of at least 50 weight percent of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238;
wherein the first side of said homogeneous single layer integrated back-sheet is adhered directly to the rear side of the solar cells, the second side of said homogeneous single layer integrated back-sheet forms an exposed surface of the photovoltaic module, and said homogeneous single layer integrated back-sheet has a thickness of at least 0.1 mm.

2. The photovoltaic module of claim 1 wherein said homogeneous single layer integrated back-sheet comprises 30 to 75 weight percent olefin-based elastomer and 25 to 70 weight percent of inorganic particulates, based on the weight of the back-sheet.

3. The photovoltaic module of claim 1 wherein said homogeneous single layer integrated back-sheet comprises:
at least 10 weight percent of a propylene ethylene elastomer comprised of at least 70 weight percent propylene derived monomer units and at least 10 weight percent of ethylene derived monomer units based on the weight of the propylene ethylene elastomer; and
at least 10 weight percent of an ethylene alpha olefin copolymer elastomer comprised of at least 70 weight percent ethylene derived monomer units and at least 1 weight percent of alpha olefin derived monomer units selected from 1-propene, isobutylene, 1-butene, 1-hexane, 4-methyl-1-pentene and 1-octene based on the weight of the ethylene alpha olefin copolymer.

4. The photovoltaic module of claim 1 wherein the inorganic particulates are selected from silica, silicates, calcium carbonate and titanium dioxide particles having an average particle diameter between and including any two of the following diameters: 0.1, 0.2, 15, 45, and 100 microns.

5. The photovoltaic module of claim 1 wherein said at least 99 percent of the inorganic particulates have an average particle diameter in the range of 0.1 to 45 microns.

6. The photovoltaic module of claim 1 wherein said homogeneous single layer integrated back-sheet further comprises 5 to 30 weight percent of one or more of thermoplastic polymer adhesives and tackifiers.

7. The photovoltaic module of claim 6 wherein the homogeneous single layer integrated back-sheet comprises 5 to 30 weight percent thermoplastic polymer adhesive that is a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the thermoplastic polymer adhesive is comprised of at least 50 weight percent ethylene derived units.

8. The photovoltaic module of claim 7 wherein said adhesive is a non-aromatic ethylene-based copolymer adhesive plastomer with a melt flow index of greater than 250.

9. The photovoltaic module of claim 1 wherein said homogeneous single layer integrated back-sheet has a thickness in the range of 0.3 to 1.3 mm.

10. The photovoltaic module of claim 1 wherein said homogeneous single layer integrated back-sheet further comprises a metal circuit layer selected from the group of metal foils, sputtered metal layers, and metal oxide layers.

11. A process for forming a photovoltaic module, comprising:
forming a homogeneous single layer integrated back-sheet by providing a polymer melt comprising 20 to 80 weight percent olefin-based elastomer, 20 to 80 weight percent of inorganic particulates, based on the weight of the polymer melt, wherein said olefin-based elastomer is a copolymer comprised of at least 50 weight percent of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238; depositing the polymer melt on a release sheet; passing the polymer melt through a nip and cooling the polymer melt to form a first polymer layer having a thickness of at least 0.1 mm;
providing a plurality of solar cells each having a front sunlight receiving side and an opposite rear side; and
pressing a first side of said homogeneous single layer integrated back-sheet directly against the rear side of said solar cells and heating said single layer integrated back-sheet to adhere the first side of said integrated back-sheet to the solar cells, wherein an opposite second side of the single layer integrated back-sheet forms an exposed exterior surface of the photovoltaic module.

12. The process of claim 11 wherein said first polymer layer comprises 30 to 75 weight percent olefin-based elastomer and 25 to 70 weight percent of inorganic particulates, based on the weight of the polymer melt.

13. The process of claim 11 wherein the polymer melt comprises at least 10 weight percent of a propylene ethylene elastomer comprised of at least 70 weight percent propylene derived monomer units and at least 10 weight percent of ethylene derived monomer units based on the weight of the propylene ethylene elastomer.

14. The process of claim 11 wherein the polymer melt comprises at least 10 weight percent of an ethylene alpha olefin copolymer elastomer comprised of at least 70 weight percent ethylene derived monomer units and at least 1 weight percent of alpha olefin derived monomer units selected from 1-propene, isobutylene, 1-butene, 1-hexane, 4-methyl-1-pentene and 1-octene, based on the weight of the ethylene alpha olefin copolymer elastomer.

15. The process of claim 11 wherein said inorganic particulates are selected from silica, silicates, calcium carbonate and titanium dioxide particles having an average particle diameter between and including any two of the following diameters: 0.1, 0.2, 15, 45, and 100 microns.

16. The process of claim 11 wherein said polymer melt further comprises 5 to 30 weight percent of one or more of thermoplastic polymer adhesives and tackifiers.

17. The process of claim 16 wherein the polymer melt comprises thermoplastic polymer adhesive that is a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the thermoplastic polymer adhesive is comprised of at least 50 weight percent ethylene derived units.

18. The process of claim 17 wherein said adhesive is a non-aromatic ethylene-based copolymer adhesive plastomer with a melt flow index of greater than 250.

19. The process of claim 11 wherein said polymer melt is melted between heated calendar rolls and wherein said polymer melt is deposited from said heated calendar rolls onto said release sheet and passed through a nip to form a polymer layer having a thickness of at least 0.1 mm.

20. The process of claim 19 wherein the formed polymer layer has a thickness in the range of 0.3 to 1.3 mm.
